(19) United States
(12) Patent Application Publication
(10) Pub. No.: US 2026/0096348 A1
(43) Pub. Date: Apr. 2, 2026

(54) PIEZOELECTRIC ELEMENT AND LIQUID EJECTION HEAD

(71) Applicant: SEIKO EPSON CORPORATION, Tokyo (JP)

(72) Inventors: Nobuo OZAWA, CHINO-SHI (JP); Takatoshi YAMAZAKI, SHIOJIRI-SHI (JP); Toshihiro SHIMIZU, FUJIMI-MACHI (JP); Shunsuke YOSHIDA, MATSUMOTO-SHI (JP)

(21) Appl. No.: 19/342,868

(22) Filed: Sep. 29, 2025

(30) Foreign Application Priority Data
Sep. 30, 2024 (JP) 2024-170656

(51) Int. Cl. H10N 30/853; B41J 2/14; H10N 30/00

(52) U.S. Cl. CPC H10N 30/8554; B41J 2/14233; H10N 30/704; B41J 2002/14258

(57) ABSTRACT

A piezoelectric element is a piezoelectric element including a piezoelectric layer including a plurality of layers and a pair of electrodes disposed with the piezoelectric layer interposed between the electrodes. The piezoelectric layer is formed of lead zirconate titanate. ΔH is 24% or less when an average value, a maximum value, and a minimum value of a content of hydrogen contained in a plurality of central layers of the piezoelectric layer are defined as H(ave), H(max), and H(min), respectively, and a larger one of absolute values of (H(max)−H(ave))/H(ave)) and (H(min)−H(ave))/H(ave)) is defined as ΔH as a change rate of the content of hydrogen.

The present application is based on, and claims priority from JP Application Serial Number 2024-170656, filed Sep. 30, 2024, the disclosure of which is hereby incorporated by reference herein in its entirety.

### BACKGROUND

### 1. Technical Field

The present disclosure relates to a piezoelectric element and a liquid ejection head.

### 2. Related Art

An image forming apparatus including a liquid ejection head that ejects a liquid such as ink onto a medium such as printing paper has been proposed. As the liquid ejection head, there is known a head that ejects a liquid charged into a pressure chamber from a nozzle by vibrating a vibrating plate constituting a wall surface of the pressure chamber by a piezoelectric element.

The piezoelectric element of the liquid ejection head described in JP-A-2010-214800 includes a pair of electrodes and a piezoelectric layer interposed between the pair of electrodes. The piezoelectric layer has a perovskite structure such as PZT.

The piezoelectric layer described in JP-A-2010-214800 includes a plurality of layers formed by a sol-gel method. Each of the layers is formed by applying and drying a coating solution containing an organic compound to form a gelled precursor film, and then firing the precursor film. By repeating the formation and firing of the precursor film a plurality of times, a piezoelectric layer including a plurality of layers is formed.

In the piezoelectric element, it is known that a composition gradient occurs in each layer depending on the crystallization temperature of the material. For example, when the piezoelectric layer is lead zirconate titanate, a large amount of titanium is likely to be segregated at an interface where crystallization is likely to proceed rapidly due to the difference in crystallization temperature between lead titanate and lead zirconate. Therefore, in each layer, the composition may be different between the vicinity of the interface and the center of the layer. When such a composition gradient occurs, the displacement characteristics of the piezoelectric element may be affected.

As a result of intensive studies, the present inventors have found that the displacement characteristics of the piezoelectric element change depending on the hydrogen content of the piezoelectric layer. This occurs even in a piezoelectric element having an equivalent composition gradient. In particular, the present inventors have found that the change rate of the hydrogen content in a central layer of the piezoelectric layer affects the displacement characteristics of the piezoelectric element.

### SUMMARY

A piezoelectric element according to a preferred aspect of the present disclosure is a piezoelectric element including a piezoelectric layer including a plurality of layers and a pair of electrodes disposed with the piezoelectric layer interposed between the electrodes. The piezoelectric layer is formed of lead zirconate titanate. ΔH is 24% or less when an average value, a maximum value, and a minimum value of a content of hydrogen contained in a plurality of central layers of the piezoelectric layer are defined as H(ave), H(max), and H(min), respectively, and a larger one of absolute values of (H(max)−H(ave))/H(ave)) and (H(min)−H(ave))/H(ave)) is defined as ΔH as a change rate of the content of hydrogen.

A liquid ejection head according to a preferred aspect of the present disclosure includes the piezoelectric element.

### BRIEF DESCRIPTION OF THE DRAWINGS

FIG. 1 is a schematic view illustrating the configuration of an image forming apparatus according to a first embodiment.

FIG. 2 is an exploded perspective view of a liquid ejection head shown in FIG. 1.

FIG. 3 is a cross-sectional view of a portion of the liquid ejection head shown in FIG. 1.

FIG. 4 is a cross-sectional view of the piezoelectric element shown in FIG. 3.

FIG. 5 is a cross-sectional view of the piezoelectric element shown in FIG. 3.

FIG. 6 is a diagram schematically showing the piezoelectric element shown in FIG. 4.

FIG. 7 is a table showing Examples and Comparative Examples.

FIG. 8 is a diagram showing a measurement result of a piezoelectric element of Example 1 with a secondary ion mass spectrometer (SIMS).

FIG. 9 is a diagram showing a measurement result of a piezoelectric element of Example 2 with a secondary ion mass spectrometer.

FIG. 10 is a diagram showing a measurement result of a piezoelectric element of Comparative Example 1 with a secondary ion mass spectrometer.

FIG. 11 is a diagram showing a measurement result of a piezoelectric element of Comparative Example 2 with a secondary ion mass spectrometer.

FIG. 12 is a diagram showing a procedure of a manufacturing method of the piezoelectric element of FIG. 6.

FIG. 13 is a diagram schematically showing a piezoelectric element of a first modification example.

FIG. 14 is a sectional view of a piezoelectric element of a second modification example.

### DESCRIPTION OF EMBODIMENTS

Hereinafter, preferred embodiments according to the present disclosure will be described with reference to the accompanying drawings. In the drawings, the size or scale of each part is different from the actual size or scale as appropriate, and some parts are schematically shown to facilitate understanding. The scope of the present disclosure is not limited to these embodiments unless it is noted in the following description that the present disclosure is particularly limited. In addition, “the element β on the element γ” is not limited to a configuration in which the element γ and the element β are in direct contact with each other, and also includes a configuration in which the element γ and the element β are not in direct contact with each other. “The element γ and the element β are equal to each other” means that the element γ and the element β need only be substantially equal to each other, and includes a manufacturing error or the like. The phrase “the element α and the element β are stacked” means that the element α and the element β need only be arranged in an up-down direction, and whether the element α and the element β are in direct contact with each other is not a problem.

### 1. First Embodiment

### 1-1. Overall Configuration of Image Forming Apparatus 100

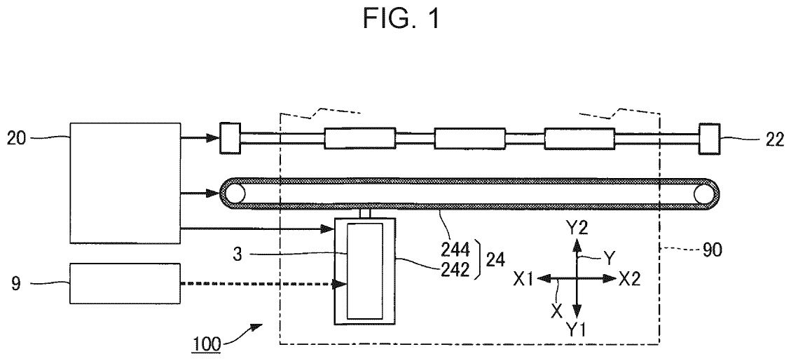

FIG. 1 is a schematic view illustrating the configuration of an image forming apparatus 100 according to a first embodiment. Hereinafter, for convenience of description, the description will be made by appropriately using an X axis, a Y axis, and a Z axis which are orthogonal to one another. One direction along the X axis is referred to as an X1 direction, and a direction opposite to the X1 direction is referred to as an X2 direction. Similarly, one direction along the Y axis is referred to as a Y1 direction, and a direction opposite to the Y1 direction is referred to as a Y2 direction. One direction along the Z axis is referred to as a Z1 direction, and a direction opposite to the Z1 direction is referred to as a Z2 direction. Viewing in a direction along the Z axis will be referred to as “plan view.” “Stacking direction” is a direction along the Z axis. The Z axis is typically a vertical axis. The Z2 direction is an upper side, and the Z1 direction is a lower side. However, the Z axis need not be the vertical axis. The X axis, the Y axis, and the Z axis are typically orthogonal to each other, but are not limited thereto, and need only intersect each other at an angle within a range of, for example, 80° or more and 100° or less.

The image forming apparatus 100 of FIG. 1 is an ink jet printing apparatus that ejects ink, which is an example of a liquid, onto a medium 90. The medium 90 is typically printing paper, but a printing target of any material such as a resin film or a cloth is used as the medium 90. As illustrated in FIG. 1, a liquid container 9 that stores ink is installed in the image forming apparatus 100. For example, a cartridge attachable to and detachable from the image forming apparatus 100, a bag-shaped ink pack formed of a flexible film, or an ink tank capable of being replenished with ink is used as the liquid container 9.

The image forming apparatus 100 includes a control unit 20, a medium transport mechanism 22, a moving mechanism 24, and a liquid ejection head 3. The control unit 20 includes, for example, one or a plurality of processing circuits such as a central processing unit (CPU) or a field programmable gate array (FPGA) and one or a plurality of memory circuits such as a semiconductor memory, and integrally controls the elements of the image forming apparatus 100.

The medium transport mechanism 22 transports the medium 90 in a direction along the Y axis under the control of the control unit 20. The moving mechanism 24 reciprocates the liquid ejection head 3 along the X axis under the control of the control unit 20. The moving mechanism 24 includes a substantially box-shaped transport body 242 housing the liquid ejection head 3, and a transport belt 244 to which the transport body 242 is fixed. A configuration in which a plurality of liquid ejection heads 3 are mounted on the transport body 242 or a configuration in which the liquid container 9 is mounted on the transport body 242 together with the liquid ejection head 3 can also be employed.

The liquid ejection head 3 ejects the ink supplied from the liquid container 9 onto the medium 90 from a plurality of nozzles under the control of the control unit 20. An image is formed on the surface of the medium 90 by each liquid ejection head 3 ejecting the ink onto the medium 90 in parallel with the transport of the medium 90 by the medium transport mechanism 22 and the repeated reciprocation of the transport body 242.

The image forming apparatus 100 is of a serial head type, in which the liquid ejection head 3 reciprocates on the medium 90. However, the image forming apparatus 100 may be of a line head type, in which the liquid ejection head 3 is fixed.

### 1-2. Overall Configuration of Liquid Ejection Head 3

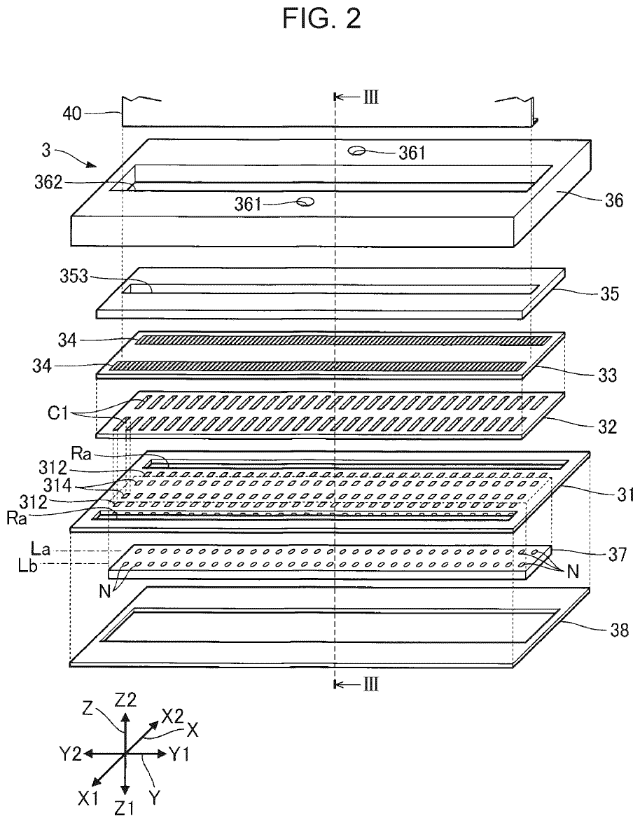

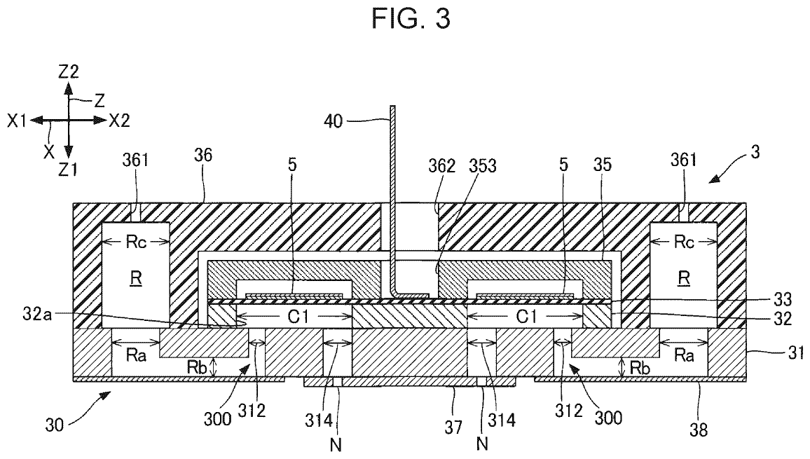

FIG. 2 is an exploded perspective view of the liquid ejection head 3 shown in FIG. 1. FIG. 3 is a cross-sectional view of a portion of the liquid ejection head shown in FIG. 1, and is a cross-sectional view taken along the line III-III in FIG. 2. The cross section shown in FIG. 3 is a cross section parallel to an X-Z plane. The Z axis is an axis line along the ejection direction of the ink by the liquid ejection head 3.

As illustrated in FIG. 2, the liquid ejection head 3 includes a plurality of nozzles N arranged along the Y axis. The nozzles N of the first embodiment are sectioned into a first row La and a second row Lb, which are provided in parallel spaced apart from each other along the X axis. Each of the first row La and the second row Lb is a set of a plurality of nozzles N linearly arranged along the Y axis. The liquid ejection head 3 has a structure in which an element related to each nozzle N in the first row La and an element related to each nozzle N in the second row Lb are disposed substantially in plane symmetry. In the following description, an element corresponding to the first row La will be mainly described, and the description of an element corresponding to the second row Lb will be omitted as appropriate.

As illustrated in FIG. 2 and FIG. 3, the liquid ejection head 3 includes a flow path forming substrate 31, a pressure chamber substrate 32, a vibrating plate 33, a nozzle plate 37, a vibration absorber 38, a plurality of piezoelectric elements 5, a sealing body 35, a housing portion 36, and a wiring board 40. Each of the flow path forming substrate 31, the pressure chamber substrate 32, the vibrating plate 33, the nozzle plate 37, the vibration absorber 38, the sealing body 35, and the housing portion 36 is an elongated plate-shaped member along the Y axis. The nozzle plate 37, the flow path forming substrate 31, the pressure chamber substrate 32, the vibrating plate 33, and the sealing body 35 are arranged in this order in the Z2 direction.

The nozzle plate 37 is a plate-shaped member in which a plurality of nozzles N are formed. Each of the nozzles Nis a circular through hole through which the ink is ejected. The nozzle plate 37 is bonded to the surface of the flow path forming substrate 31 in the Z1 direction with, for example, an adhesive.

The flow path forming substrate 31 forms a flow path through which the ink flows. Specifically, in the flow path forming substrate 31, a space Ra, a relay liquid chamber Rb, a plurality of supply flow paths 312, and a plurality of communication flow paths 314 are formed. The space Ra is an opening formed in an elongated shape along the Y axis. Each of the supply flow paths 312 and the communication flow paths 314 is a through hole formed for each nozzle N. Each of the communication flow paths 314 overlaps one corresponding nozzle N in a plan view seen from the Z1 direction. The relay liquid chamber Rb is a space formed in an elongated shape along the Y axis over the nozzles N, and causes the space Ra and the supply flow paths 312 to communicate with each other. The pressure chamber substrate 32 is bonded to the surface of the flow path forming substrate 31 in the Z2 direction with an adhesive.

A plurality of pressure chambers C1 are formed in the pressure chamber substrate 32. The ink ejected from the nozzle N is stored in the pressure chamber C1. The pressure chamber C1 is a space that is positioned between the nozzle plate 37 and the vibrating plate 33 and is formed by an inner wall surface 32a of the pressure chamber substrate 32. The pressure chamber C1 is formed for each nozzle N. The pressure chamber C1 is an elongated space and extends in the X1 direction. The pressure chambers C1 are arranged along the Y-axis. Each pressure chamber C1 communicates with the communication flow path 314 and the supply flow path 312. Therefore, the pressure chamber C1 communicates with the nozzle N via the communication flow path 314, and communicates with the space Ra via the supply flow path 312 and the relay liquid chamber Rb.

The nozzle plate 37, the flow path forming substrate 31, and the pressure chamber substrate 32 are manufactured by processing a single crystal substrate of silicon (Si) using semiconductor manufacturing techniques such as photolithography and etching. However, known materials and manufacturing methods can be freely employed to manufacture the nozzle plate 37, the flow path forming substrate 31, and the pressure chamber substrate 32.

The vibrating plate 33 is connected to the surface of the pressure chamber substrate 32 opposite to the flow path forming substrate 31. The vibrating plate 33 is disposed on the pressure chambers C1 and is elastically deformable. The vibrating plate 33 is a plate-shaped member formed in an elongated rectangular shape along the Y axis in a plan view. The vibrating plate 33 and the pressure chambers C1 may be integrally formed, or separately formed and bonded to each other with an adhesive or the like.

The piezoelectric elements 5 are formed on the surface of the vibrating plate 33 opposite to the pressure chambers C1. The piezoelectric element 5 is provided for each pressure chamber C1. The piezoelectric element 5 has an elongated shape along the X axis in a plan view. The piezoelectric element 5 is a drive element that is driven by a drive signal being applied thereto, and applies pressure to the ink in the pressure chamber C1.

The sealing body 35 is bonded to the vibrating plate 33 with, for example, an adhesive. The sealing body 35 is a structure that protects the piezoelectric elements 5 and reinforces the mechanical strength of the pressure chamber substrate 32 and the vibrating plate 33. In the sealing body 35, a recess is formed on the surface facing the vibrating plate 33. The piezoelectric elements 5 are housed inside the recess. The sealing body 35 has a space 353 into which the wiring board 40 is inserted.

The housing portion 36 is bonded to the flow path forming substrate 31 with, for example, an adhesive. The housing portion 36 is a case for storing the ink to be supplied to the pressure chambers C1. The housing portion 36 is formed by injection molding of a resin material, for example. A space Rc, a supply port 361, and a space 362 are formed in the housing portion 36. The supply port 361 is a conduit through which the ink is supplied from the liquid container 9, and communicates with the space Rc. The space Rc communicates with the space Ra of the flow path forming substrate 31. A space formed by the space Rc and the space Ra functions as a liquid storage chamber R that stores the ink to be supplied to the pressure chambers C1. The ink that has been supplied from the liquid container 9 and passed through the supply port 361 is stored in the liquid storage chamber R. The ink stored in the liquid storage chamber R is branched from the relay liquid chamber Rb to the respective supply flow paths 312, and is supplied to the pressure chambers C1 in parallel. The space 362 overlaps the space 353 of the sealing body 35 in a plan view. The wiring board 40 is inserted into the space 353 and the space 362.

The wiring board 40 is connected to the vibrating plate 33. The wiring board 40 is a mounted component on which a plurality of wires for electrically connecting the control unit 20 and the liquid ejection head 3 to each other are formed. For example, a flexible board such as a flexible printed circuit (FPC) or a flexible flat cable (FFC) is preferably employed as the wiring board 40. A drive signal for driving the piezoelectric element 5 and a reference voltage are supplied to each piezoelectric element 5 from the wiring board 40.

The vibration absorber 38 is bonded to the surface of the flow path forming substrate 31 in the Z1 direction with, for example, an adhesive. The vibration absorber 38 is a flexible film constituting a wall surface of the space Ra and absorbs pressure fluctuations of the ink inside the liquid storage chamber R.

In the liquid ejection head 3, when the piezoelectric element 5 is flexurally deformed by the application of a voltage, the vibrating plate 33 is flexurally deformed, that is, vibrates in a direction in which the volume of the pressure chamber C1 decreases. As a result, the pressure in the pressure chamber C1 changes, and the ink inside the pressure chamber C1 is ejected from the nozzle N. After the ink ejection, the piezoelectric element 5 is restored to its original position.

Although the liquid ejection head 3 includes all of the elements shown in FIG. 3, the constituent elements of the liquid ejection head 3 may not include all of the elements, and may further include additional elements.

### 1-3. Piezoelectric Element 5

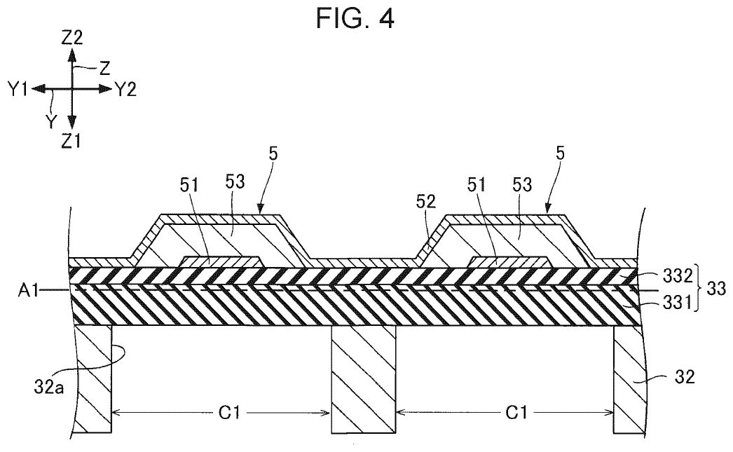

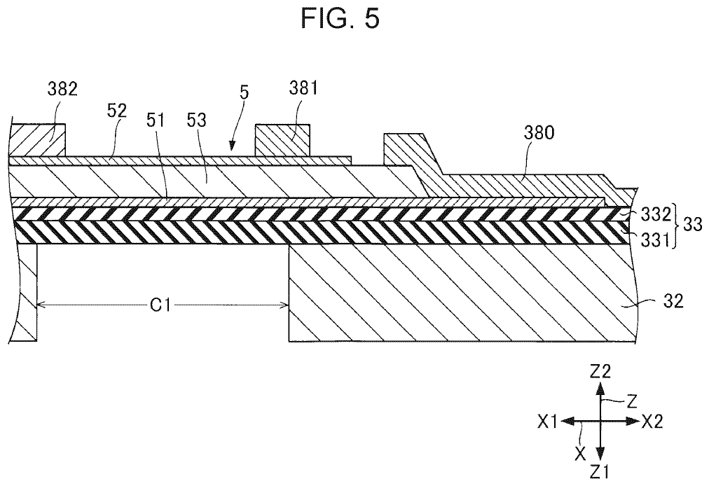

FIG. 4 and FIG. 5 are each a cross-sectional view showing the piezoelectric element 5 of FIG. 3. The cross section shown in FIG. 4 is a cross section parallel to a Y-Z plane. The cross section shown in FIG. 5 is a cross section parallel to the X-Z plane.

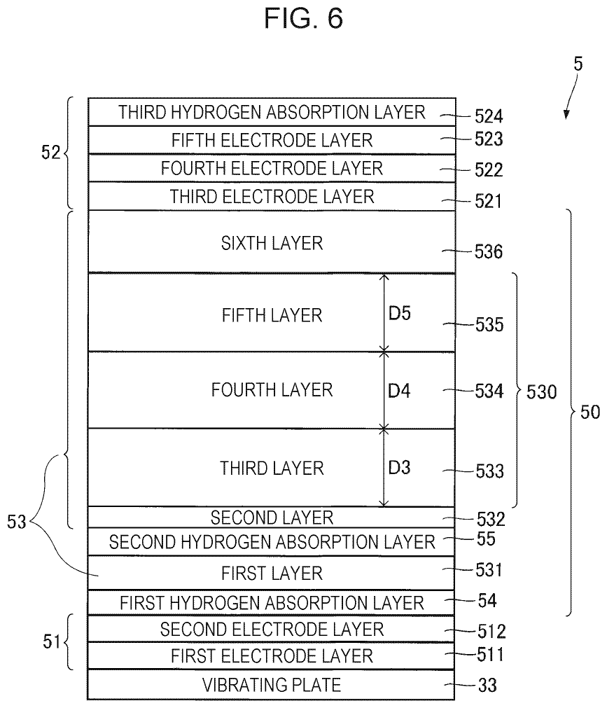

As shown in FIG. 4 and FIG. 5, the piezoelectric element 5 mainly includes a lower electrode 51, a piezoelectric layer 53, and an upper electrode 52. The lower electrode 51, the piezoelectric layer 53, and the upper electrode 52 are stacked in a direction along the Z-axis, which is the stacking direction. As will be described later, as shown in FIG. 6, the piezoelectric element 5 further includes a first hydrogen absorption layer 54 and a second hydrogen absorption layer 55. The piezoelectric layer 53, the first hydrogen absorption layer 54, and the second hydrogen absorption layer 55 may be collectively referred to as an intermediate layer 50 positioned between the lower electrode 51 and the upper electrode 52. As will be described later, the upper electrode 52 includes a third hydrogen absorption layer 524. Each of the first hydrogen absorption layer 54 and the third hydrogen absorption layer 524 corresponds to “hydrogen absorption layer.”

As shown in FIG. 4 and FIG. 5, the lower electrode 51 is provided above the vibrating plate 33. The lower electrode 51 is an individual electrode provided for each piezoelectric element 5. A drive signal whose voltage varies is applied to the lower electrode 51. The lower electrode 51 has an elongated shape along the X-axis. A plurality of the lower electrodes 51 are disposed spaced apart from each other along the Y-axis. The lower electrode 51 includes a conductive material.

The piezoelectric layer 53 is provided above the lower electrode 51. The piezoelectric layer 53 is, for example, a band-shaped dielectric film that is continuous along the Y axis over the piezoelectric elements 5. The piezoelectric layer 53 has, for example, a band shape extending along the Y axis, and is separated for each piezoelectric element 5 by a plurality of notches being formed. The piezoelectric layer 53 is formed of, for example, a perovskite type composite oxide.

The upper electrode 52 is provided above the piezoelectric layer 53. The upper electrode 52 is a band-shaped common electrode extending along the Y axis so as to be continuous over the piezoelectric elements 5. A predetermined reference voltage is applied to the upper electrode 52. The upper electrode 52 includes a conductive material.

A voltage corresponding to the difference between the reference voltage applied to the upper electrode 52 and the drive signal corresponding to an ejection amount supplied to the lower electrode 51 is applied to the piezoelectric layer 53. When a voltage is applied between the lower electrode 51 and the upper electrode 52, the piezoelectric layer 53 is deformed, and thus the piezoelectric element 5 is flexurally deformed, that is, vibrates.

The vibrating plate 33 vibrates by driving the piezoelectric element 5. In the shown example, the vibrating plate 33 includes a stacked body including a first vibrating body layer 331 and a second vibrating body layer 332. The first vibrating body layer 331 is in contact with the pressure chamber substrate 32. The second vibrating body layer 332 is disposed above the first vibrating body layer 331. The first vibrating body layer 331 is formed of an elastic material such as silicon oxide (SiOₓ). The second vibrating body layer 332 is formed of an insulating material such as zirconium oxide (ZrOₓ). The first vibrating body layer 331 is formed by, for example, thermally oxidizing a portion of the pressure chamber substrate 32. The second vibrating body layer 332 is formed by, for example, a known film forming technique such as sputtering. The vibrating plate 33 may include one layer or include three or more layers.

FIG. 4 shows a neutral axis A1 of the vibrating plate 33. The neutral axis A1 is a position at which a compression force and a contraction force are balanced, and is a position at which stress in an axial direction along an X-Y plane of the vibrating plate 33 is 0 (zero).

As shown in FIG. 5, two conductors 381 and 382 are disposed on the upper electrode 52. Each of the conductors 381 and 382 is a band-shaped conductive film that is disposed along the edge of the upper electrode 52 in the X1 direction or the X2 direction and extends in a direction along the Y axis. The conductors 381 and 382 are formed of, for example, a conductive material having an electrically low resistance, such as gold. The conductors 381 and 382 inhibit a voltage drop of the reference voltage in the upper electrode 52. The conductors 381 and 382 also function as a weight that defines a vibration region of the vibrating plate 33. The conductors 381 and 382 may be omitted.

A connection wire 380 is connected to one end of the lower electrode 51 in the longitudinal direction along the X axis. The lower electrode 51 is electrically connected to the wiring board 40 via the connection wire 380. The upper electrode 52 is electrically connected to the wiring board 40 described above via a wire (not shown) or the like.

In the present embodiment, the lower electrode 51 is an individual electrode and the upper electrode 52 is a common electrode, but the lower electrode 51 may be a common electrode and the upper electrode 52 may be an individual electrode.

FIG. 6 is a diagram schematically showing the piezoelectric element 5 shown in FIG. 4. As described above, the piezoelectric element 5 includes the lower electrode 51, the piezoelectric layer 53, the upper electrode 52, the first hydrogen absorption layer 54, and the second hydrogen absorption layer 55. Each of the lower electrode 51, the piezoelectric layer 53, and the upper electrode 52 includes a plurality of layers. In the present embodiment, the first hydrogen absorption layer 54 is disposed between the lower electrode 51 and the piezoelectric layer 53. The second hydrogen absorption layer 55 is disposed between the layers constituting the piezoelectric layer 53. The upper electrode 52 includes the third hydrogen absorption layer 524. Each of the first hydrogen absorption layer 54 and the third hydrogen absorption layer 524 corresponds to “hydrogen absorption layer.”

The lower electrode 51 includes a first electrode layer 511 and a second electrode layer 512. The first electrode layer 511 is disposed above the vibrating plate 33 and is in contact with the vibrating plate 33. The first electrode layer 511 includes, for example, platinum (Pt). The thickness of the first electrode layer 511 along the Z axis is not particularly limited, and is, for example, 50 nm or more and 120 nm or less.

The second electrode layer 512 is disposed between and in contact with the first electrode layer 511 and the first hydrogen absorption layer 54. The second electrode layer 512 includes, for example, iridium (Ir). The thickness of the second electrode layer 512 along the Z axis is not particularly limited, and is, for example, 5 nm or more and 50 nm or less. In the present embodiment, the thickness of the second electrode layer 512 is smaller than the thickness of the first electrode layer 511, but may be equal to or larger than the thickness of the first electrode layer 511.

In the present embodiment, the lower electrode 51 includes two layers, but may include one layer or include three or more layers. The first electrode layer 511 and the second electrode layer 512 may be formed of a conductive material, and may be formed of a material other than the materials described above.

The first hydrogen absorption layer 54 is “hydrogen absorption layer.” The first hydrogen absorption layer 54 is provided between the lower electrode 51 and the piezoelectric layer 53, above the lower electrode 51 in a direction along the Z axis, which is the stacking direction of the piezoelectric element 5. The first hydrogen absorption layer 54 has a function of absorbing hydrogen. According to the piezoelectric element 5 including the first hydrogen absorption layer 54, it is possible to absorb hydrogen present at the interface between the lower electrode 51 and another layer, hydrogen present in the piezoelectric layer 53, or hydrogen which may enter the piezoelectric layer 53.

In FIG. 6, the interface between the first hydrogen absorption layer 54 and the piezoelectric layer 53 is clearly shown, but may not be clear. For example, a portion of the first hydrogen absorption layer 54 may be embedded in, dispersed in, or integrated with the piezoelectric layer 53. The composition in the first hydrogen absorption layer 54 may be constant or graded. Therefore, the piezoelectric layer 53 side and the lower electrode 51 side of the first hydrogen absorption layer 54 may have different compositions. The thickness of the first hydrogen absorption layer 54 along the Z axis is not particularly limited, and is, for example, 2 nm or more and 20 nm or less. The first hydrogen absorption layer 54 may include a plurality of layers.

The piezoelectric layer 53 is a stacked body in which a first layer 531, a second layer 532, a third layer 533, a fourth layer 534, a fifth layer 535, and a sixth layer 536 are stacked in this order. The piezoelectric layer 53 includes a central layer 530. The central layer 530 includes a plurality of central layers of the piezoelectric layer 53. Specifically, the central layer 530 includes the third layer 533, the fourth layer 534, and the fifth layer 535. The number of layers included in the piezoelectric layer 53 is not limited to six, and may be five or less or seven or more. However, when the piezoelectric layer 53 includes not a single layer but a plurality of layers, the piezoelectric layer 53 having excellent piezoelectric characteristics can be formed.

Each layer constituting the piezoelectric layer 53 is formed of a perovskite type composite oxide. More specifically, each layer is formed of lead zirconate titanate (PZT: Pb(Zr,Ti)O₃).

The thickness of each layer of the piezoelectric layer 53 is not particularly limited, and is, for example, 90 nm or more and 250 nm or less.

The first layer 531 is disposed between and in contact with the first hydrogen absorption layer 54 and the second hydrogen absorption layer 55. The second hydrogen absorption layer 55 is disposed between and in contact with the first layer 531 and the second layer 532.

The second hydrogen absorption layer 55 has a function of absorbing hydrogen present in each layer or between layers constituting the piezoelectric element 5. In particular, the second hydrogen absorption layer 55 suitably absorbs hydrogen in the first layer 531 and the second layer 532.

In FIG. 6, each of the interface between the second hydrogen absorption layer 55 and the second layer 532 and the interface between the second hydrogen absorption layer 55 and the first layer 531 is clearly shown, but may not be clear. For example, a portion of the second hydrogen absorption layer 55 may be embedded in, dispersed in, or integrated with the first layer 531 or the second layer 532. The composition in the second hydrogen absorption layer 55 may be constant or graded. Therefore, the second layer 532 side and the first layer 531 side of the second hydrogen absorption layer 55 may have different compositions. The thickness of the second hydrogen absorption layer 55 along the Z axis is not particularly limited, and is, for example, 2 nm or more and 20 nm or less. In the present embodiment, a film thickness D5 of the second hydrogen absorption layer 55 is smaller than a film thickness D4 of the first hydrogen absorption layer 54, but may be equal to or larger than the film thickness D4 of the first hydrogen absorption layer 54. The second hydrogen absorption layer 55 may include a plurality of layers.

The upper electrode 52 is a structure in which a third electrode layer 521, a fourth electrode layer 522, a fifth electrode layer 523, and the third hydrogen absorption layer 524 are stacked in this order. The third electrode layer 521 is disposed above the piezoelectric layer 53 and is in contact with the sixth layer 536 of the piezoelectric layer 53. The third electrode layer 521 includes, for example, iridium oxide (IrOₓ). The thickness of the third electrode layer 521 along the Z axis is not particularly limited, and is, for example, 5 nm or more and 20 nm or less. The fourth electrode layer 522 includes, for example, titanium oxide (TiOₓ). The thickness of the fourth electrode layer 522 along the Z axis is not particularly limited, and is, for example, 2 nm or more and 20 nm or less. The fifth electrode layer 523 includes, for example, iridium (Ir). The thickness of the fifth electrode layer 523 along the Z axis is not particularly limited, and is, for example, 5 nm or more and 50 nm or less.

The third hydrogen absorption layer 524 is “hydrogen absorption layer.” The third hydrogen absorption layer 524 is provided on the upper electrode 52 side with respect to the piezoelectric layer 53, and is provided as the uppermost layer of the upper electrode 52. The third hydrogen absorption layer 524 has a function of absorbing hydrogen. When the third hydrogen absorption layer 524 is provided, the entry of hydrogen into the piezoelectric layer 53 from the upper electrode 52 side can be inhibited compared to a case where the third hydrogen absorption layer 524 is not provided. Each hydrogen content of the third electrode layer 521 to the fifth electrode layer 523 can be reduced.

The thickness of the third hydrogen absorption layer 524 along the Z axis is not particularly limited, and is, for example, 5 nm or more and 20 nm or less. The third hydrogen absorption layer 524 has a function of absorbing hydrogen present in each layer or between layers constituting the piezoelectric element 5. In particular, the third hydrogen absorption layer 524 suitably absorbs hydrogen in the upper electrode 52. The composition in the third hydrogen absorption layer 524 may be constant or graded. The third hydrogen absorption layer 524 may be formed of a plurality of layers.

In the example of FIG. 6, an orientation control layer that controls the orientation of the piezoelectric layer 53 is not provided between the first hydrogen absorption layer 54 and the piezoelectric layer 53, but the orientation control layer may be provided. The first hydrogen absorption layer 54 may have a function of the orientation control layer. When the first hydrogen absorption layer 54 has the function of the orientation control layer, it is not necessary to separately provide the orientation control layer, and thus the manufacture is easy. The orientation control layer, for example, preferentially orients the crystals of the upper layer to a predetermined plane orientation, or adjusts the degree of orientation of a predetermined plane orientation.

Similarly, an orientation control layer that controls the orientation of the second layer 532 is not provided between the second hydrogen absorption layer 55 and the second layer 532, but the orientation control layer may be provided. The second hydrogen absorption layer 55 may have a function of the orientation control layer. However, when the second hydrogen absorption layer 55 has the function of the orientation control layer, it is not necessary to separately provide an orientation control layer, and thus the manufacture is easy.

### 1-4. Piezoelectric Layer

As described above, the piezoelectric layer 53 includes a plurality of layers. The piezoelectric layer 53 is interposed between the lower electrode 51 and the upper electrode 52, which are a pair of electrodes. The layers constituting the piezoelectric layer 53 include the central layer 530 corresponding to “a plurality of central layers.” In the present embodiment, the central layer 530 is the third layer 533, the fourth layer 534, and the fifth layer 535. The central layer 530 is a layer positioned at the center and in the vicinity of the center of the piezoelectric layer 53, is a layer not in contact with the upper electrode 52, the lower electrode 51, or the second hydrogen absorption layer 55 positioned above and below the piezoelectric layer 53, and is a layer interposed between the other layers of the piezoelectric layer 53. Therefore, the central layer 530 is not in contact with any layer other than the layers constituting the piezoelectric layer 53 of the piezoelectric layer 53. The layers constituting the piezoelectric layer 53 include “one central layer.” In the present embodiment, “one central layer” is the third layer 533, the fourth layer 534, or the fifth layer 535. “One central layer” is one layer of the central layer 530, and is a layer not in contact with the upper electrode 52, the lower electrode 51, or the second hydrogen absorption layer 55, which are positioned above and below the piezoelectric layer 53. Hereinafter, a case where “one central layer” is the third layer 533 will be mainly described.

A change rate ΔH of the content of hydrogen of the central layer 530 of the piezoelectric layer 53 is 24% or less.

The change rate ΔH is a larger one of the absolute values of (H(max)−H(ave))/H(ave) and (H(min)−H(ave))/H(ave)).

H(ave) is the average value of the content of hydrogen in the third layer 533. H(max) is the maximum value of the content of hydrogen in the third layer 533. H(min) is the minimum value of the content of hydrogen in the third layer 533. H(ave), H(max), and H(min) are measured by, for example, secondary ion mass spectrometry.

When the change rate ΔH of the content of hydrogen of the central layer 530 is 24% or less, a decrease in the displacement characteristics of the piezoelectric element 5 can be reduced compared to a case where ΔH exceeds 24%.

The hysteresis characteristics of the piezoelectric element 5 change over time depending on the content of hydrogen in the piezoelectric layer 53, and largely changes from a design stage. As a result, the displacement characteristics of the piezoelectric element 5 decrease over time. In addition, a displacement amount obtained from a drive voltage value set at the design stage changes. When the piezoelectric layer 53 includes a plurality of layers, the displacement characteristics significantly decrease. As will be described later, the piezoelectric layer 53 is formed by repeating the formation and firing of each of the layers a plurality of times. In this manufacturing process, it is considered that the content of hydrogen in the piezoelectric layer 53 changes when hydrogen enters the piezoelectric layer 53. Furthermore, when a plurality of piezoelectric elements 5 are compared with each other, even when a composition gradient is similarly generated in the piezoelectric layer 53, a decrease in the displacement characteristics of the piezoelectric element 5 is observed depending on the content of hydrogen.

As a result of intensive studies, the inventors have found that a decrease in the displacement characteristics of the piezoelectric element 5 over time can be reduced by reducing the change rate ΔH of the content of hydrogen in the central layer 530 of the piezoelectric layer 53 to be small. Specifically, when the change rate ΔH is 21% or less, the decrease in the displacement characteristics of the piezoelectric element 5 can be reduced. Since the decrease in the displacement characteristics of the piezoelectric element 5 can be reduced from the design stage, it is not necessary to remake the drive voltage or the waveform in accordance with the change over time to adjust the difference, and thus usability can be improved.

The central layer 530 of the piezoelectric layer 53 has a great influence on the displacement characteristics of the piezoelectric element 5. For example, it is considered that this is influenced by the fact that the performance of the piezoelectric element 5 becomes higher as the range of the layer separated from the neutral axis A1 of the piezoelectric layers 53 is larger. It is considered that by reducing the change rate ΔH of the content of hydrogen in the central layer 530 to be small, the change rate of the content of hydrogen in the other layers and an average hydrogen content in the piezoelectric layer 53 can be reduced.

Since the central layer 530 is a layer that is not in contact with the upper electrode 52, the lower electrode 51, or the second hydrogen absorption layer 55, and is a layer interposed between the other layers of the piezoelectric layer 53, a hydrogen amount can be measured while reducing the influence from the upper electrode 52, the lower electrode 51, or the second hydrogen absorption layer 55. For example, when a layer in contact with the upper electrode 52 or the lower electrode 51 is measured by secondary ion mass spectrometry, the measurement may be unstable due to the influence of the interface between the upper electrode 52 or the lower electrode 51 and the layer. In other words, secondary ion intensity in the vicinity of the interface may be greatly changed by the interface effect. By measuring the central layer that is not in contact with the upper electrode 52 or the lower electrode 51, the hydrogen amount can be measured while reducing the influence from the upper electrode 52 or the lower electrode 51.

When the change rate ΔH of the content of hydrogen in the central layer 530 is 21% or less, it is possible to inhibit an increase in the difference in a displacement amount among the piezoelectric elements 5. Thus, it is possible to save time and effort to remake the drive voltage and the waveform for each piezoelectric element 5 in order to adjust the difference in the displacement amount among the piezoelectric elements 5. Therefore, the usability of the piezoelectric element 5 can be improved.

The change rate ΔH of the content of hydrogen may be 24% or less, and is more preferably 20% or less. When the change rate ΔH is 20% or less, a decrease in the displacement characteristics of the piezoelectric element 5 can be reduced compared to a case where the change rate ΔH exceeds 20%.

In the central layer 530, the average hydrogen content of the third layer 533, which is the lower layer in the stacking direction, is preferably smaller than each of the average hydrogen content of the fourth layer 534 and the average hydrogen content of the fifth layer 535, which are the upper layers. It is considered that when the hydrogen content of the third layer 533 is smaller than the hydrogen content of the fourth layer 534 and the hydrogen content of the fifth layer 535, the hydrogen contents of the first layer 531, the second layer 532, and the third layer 533 can be reduced by the first hydrogen absorption layer 54 and the second hydrogen absorption layer 55. It is considered that by reducing the hydrogen content of the lower layer of the piezoelectric layer 53, the entry and diffusion of hydrogen in the upper layer can be reduced in the manufacture of the piezoelectric layer 53. Therefore, when the hydrogen content of the third layer 533 is smaller than each of the hydrogen content of the fourth layer 534 and the hydrogen content of the fifth layer 535, the hydrogen content of the entire piezoelectric layer 53 can be reduced. Therefore, the displacement characteristics of the piezoelectric element 5 can be improved. The hydrogen content of the fourth layer 534 is preferably smaller than the hydrogen content of the fifth layer 535. The hydrogen content of each layer is measured using, for example, secondary ion mass spectrometry, and the average hydrogen content is calculated by averaging the hydrogen content in the layer.

In the third layer 533 of the central layer 530, the hydrogen content on the lower side in the stacking direction is preferably larger than the hydrogen content on the upper side. In other words, the third layer 533 has a low hydrogen content at a position away from the neutral axis A1 of the piezoelectric layers 53. Therefore, a decrease in the displacement characteristics of the piezoelectric element 5 can be reduced. The lower side of the layer refers to a portion of the layer positioned in the Z1 direction. For example, it refers to a range from the lower surface of the layer in the Z1 direction to 25 nm in the Z2 direction. Similarly, the upper side of the layer refers to a portion of the layer positioned in the Z2 direction. For example, it refers to a range from the upper surface of the layer in the Z2 direction to 25 nm in the Z1 direction. The hydrogen content in the range is measured using, for example, secondary ion mass spectrometry.

Also in the fourth layer 534 and the fifth layer 535, the hydrogen content on the lower side in the stacking direction is preferably larger than the hydrogen content on the upper side.

The thickness of each layer of the central layer 530 in the piezoelectric layer 53 is not particularly limited, and is preferably 100 nm or more and 300 nm or less. For example, a film thickness D3 of the third layer 533 is not particularly limited, and is preferably 100 nm or more and 300 nm or less.

As will be described later, the manufacturing step of the piezoelectric layer 53 may include a degreasing step and a firing step. In this case, hydrogen in the precursor of each layer constituting the piezoelectric layer 53 may not be sufficiently removed in the degreasing step, or hydrogen may enter the piezoelectric layer 53 in the firing step. In particular, when the piezoelectric layer 53 is formed using a sol-gel method, there is a high possibility that hydrogen cannot be completely removed. When the film thickness D3 is 100 nm or more and 300 nm or less, hydrogen is easily removed in the degreasing step, and the time of the firing step is shortened, whereby hydrogen can be made less likely to enter than a case where the thickness is out of the range.

Similarly, the film thickness D3 of the third layer 533, the film thickness D4 of the fourth layer 534, and the film thickness D5 of the fifth layer, each of which is one central layer of the layers constituting the piezoelectric layer 53, are not particularly limited, and are preferably 100 nm or more and 300 nm or less.

When the piezoelectric layer 53 is formed of a perovskite type composite oxide containing Ti, a change rate ΔTi of the content of titanium of the central layer 530 is preferably 14% or less.

The change rate ΔTi is a larger one of the absolute values of (Ti(max)−Ti(ave))/Ti(ave)) and (Ti(min)−Ti(ave))/Ti(ave)).

Ti(ave) is the average value of the content of titanium in the central layer 530. Ti(max) is the maximum value of the content of titanium in the central layer 530. Ti(min) is the minimum value of the content of titanium in the central layer 530. Ti(ave), Ti(max), and Ti(min) are measured by, for example, secondary ion mass spectrometry.

The composition gradient of titanium in the piezoelectric layer 53 affects the displacement characteristics of the piezoelectric element 5. When the change rate ΔTi of the central layer 530 of the piezoelectric layer 53 is 14% or less, the composition gradient of titanium in the piezoelectric layer 53 is reduced compared to a case where the change rate ΔTi exceeds 14%, and thus a decrease in the displacement characteristics can be reduced. Titanium has high hydrogen storage properties. Therefore, when the variation in the content of titanium is large, the variation in the hydrogen content in the piezoelectric layer 53 becomes large. Therefore, by reducing the variation in the content of titanium, the variation in the content of hydrogen can be reduced. Therefore, the displacement characteristics can be improved.

Each of the first hydrogen absorption layer 54 and the third hydrogen absorption layer 524 corresponds to “hydrogen absorption layer.” The first hydrogen absorption layer 54 and the third hydrogen absorption layer 524 are provided at positions interposing the piezoelectric layer 53 therebetween in the stacking direction of the layers constituting the piezoelectric layer 53. The piezoelectric layer 53 is provided between the first hydrogen absorption layer 54 and the third hydrogen absorption layer 524.

Hydrogen in the piezoelectric layer 53 increases due to its generation during degreasing and firing of the precursor and its entry from the outside of the piezoelectric element 5. By providing the first hydrogen absorption layer 54 and the third hydrogen absorption layer 524, the hydrogen content in the piezoelectric layer 53 can be reduced compared to a case where they are not provided.

Furthermore, in the present embodiment, the second hydrogen absorption layer 55 is provided. Therefore, the hydrogen content of the piezoelectric layer 53 can be further reduced.

The first hydrogen absorption layer 54 is formed of a material capable of absorbing hydrogen. Specifically, the first hydrogen absorption layer 54 includes a hydrogen storage material that can be combined with hydrogen to form a hydride. The hydrogen storage material absorbs or releases hydrogen depending on temperature or pressure. When the first hydrogen absorption layer 54 absorbs hydrogen, hydrogen enters gaps in the crystal lattice of the hydrogen storage material. The hydrogen storage material includes metals such as magnesium (Mg), vanadium (V), lanthanum (La), and titanium (Ti), and alloys or compounds containing the metals. The first hydrogen absorption layer 54 is formed of, for example, titanium or lead titanate (PbTiO₃). The first hydrogen absorption layer 54 is formed of, for example, a composite oxide containing bismuth (Bi), iron (Fe), titanium (Ti), and lead (Pb).

Similarly, each of the second hydrogen absorption layer 55 and the third hydrogen absorption layer 524 includes a hydrogen storage material that can be combined with hydrogen to form a hydride.

As described above, the piezoelectric layer 53 is formed of lead zirconate titanate (PZT), which is a perovskite type composite oxide. When the piezoelectric layer 53 is PZT, the effect of reducing a change in the hysteresis characteristics of the piezoelectric element 5 due to the provision of the first hydrogen absorption layer 54 is particularly remarkably exhibited. Furthermore, when the piezoelectric layer 53 includes a plurality of layers, the effect by providing the first hydrogen absorption layer 54 can be particularly remarkably exhibited.

It is particularly preferable that each of the first hydrogen absorption layer 54, the second hydrogen absorption layer 55, and the third hydrogen absorption layer 524 include titanium. Furthermore, each of these layers is preferably formed of titanium. Titanium is excellent in hydrogen absorption performance. Therefore, when these layers include titanium, a larger amount of hydrogen that may enter the piezoelectric layer 53 can be absorbed compared to a case where these layers do not contain titanium.

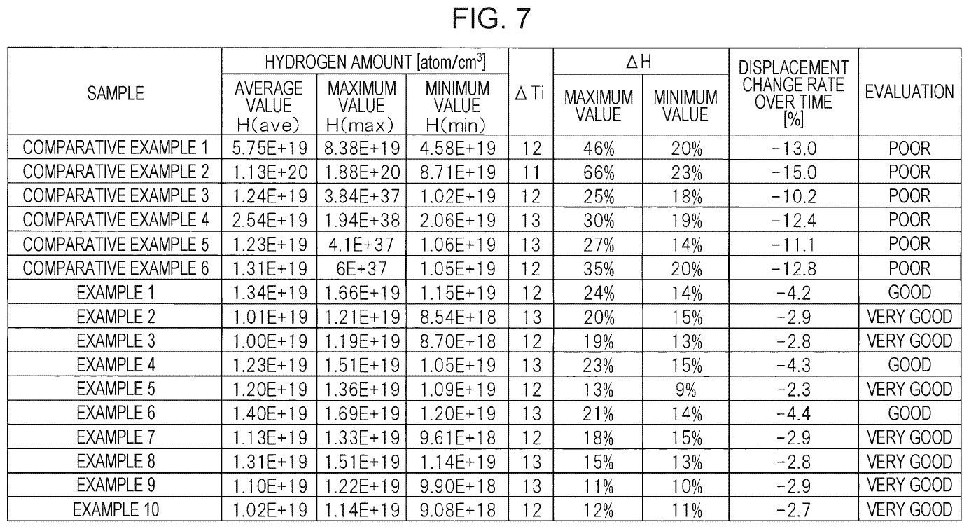

FIG. 7 is a table showing Examples and Comparative Examples. FIG. 7 shows Examples 1 to 10 and Comparative Examples 1 to 6. Examples 1 to 10 and Comparative Examples 1 to 6 have the piezoelectric layer 53 including six layers. The film thickness of each layer of the piezoelectric layer 53 is about 220 nm. FIG. 7 shows the results and the evaluation of the hydrogen amount and the change rates ΔTi and ΔH in the central layer 530 measured and calculated by secondary ion mass spectrometry.

Each of the piezoelectric layers 53 of Examples 1 to 10 is formed of lead zirconate titanate, which is a perovskite type composite oxide containing Ti. Examples 1 to 10 and Comparative Examples 1 to 6 are different from each other in the content of hydrogen in the central layer 530. The content of hydrogen in the central layer 530 was adjusted by changing the heating conditions in the manufacturing method and the hydrogen amount in the hydrogen absorption layers. In addition to Examples shown in FIG. 7 and the configuration of the piezoelectric element 5 shown in FIG. 6, examples of configurations shown in modification examples described below are included. A first modification example described below corresponds to Example 9, and a second modification example described below corresponds to Example 10.

As shown in FIG. 7, in Examples 1 to 10, as the change rate ΔH of the content of hydrogen in the central layer 530, the larger one of the absolute values of (H(max)−H(ave))/H(ave)) and (H(min)−H(ave))/H(ave)) is 24% or less. On the other hand, in Comparative Examples 1 to 6, as the change rate ΔH of the content of hydrogen in the third layer 533, the larger one of the absolute values of (H(max)−H(ave))/H(ave)) and (H(min)−H(ave))/H(ave)) exceeds 24%.

Each of Examples is superior to each of Comparative Examples in the displacement characteristics. The evaluation is based on a displacement change rate of the piezoelectric element 5 over time. A durability test in which a predetermined drive pulse was continuously applied to a liquid ejection head including the piezoelectric element 5 ten billion times was performed, and the displacement change rate over time of the piezoelectric element 5 before and after the application of the predetermined drive pulse was determined. The predetermined drive pulse has a trapezoidal waveform with a voltage of 25 V and a frequency of 100 Hz. The evaluation “good” indicates that the displacement change rate over time is less than −5.0%. The evaluation “very good” indicates that the change rate over time is less than −3.0%.

ΔH of Examples 1 to 10 is less than 24%, whereas ΔH of Comparative Examples 1 to 6 exceeds 24%. Therefore, the displacement change rate over time of the piezoelectric element 5 is lower in each of Examples than in each of Comparative Examples. Therefore, Examples 1 to 10 can reduce a decrease in the displacement characteristics of the piezoelectric element 5 compared to Comparative Examples 1 to 6. Therefore, according to the liquid ejection head including the piezoelectric element 5 of Examples 1 to 10, excellent ejection characteristics can be exhibited and maintained.

In Examples 1, 2, 5, and 7 to 10, the change rate ΔH of the content of hydrogen in the central layer 530 is 20% or less. In Examples 1, 2, 5, and 7 to 10, the change rate over time is less than −3.0%, and the change rate over time is very small. Therefore, Examples 1, 2, 5, and 7 to 10 can reduce a decrease in the displacement characteristics of the piezoelectric element 5 compared to the other Examples. Therefore, the liquid ejection head including the piezoelectric element 5 of Examples 1, 2, 5, and 7 to 10 can exhibit and maintain particularly excellent ejection characteristics.

In Examples 1 to 10, the change rate ΔTi of the content of titanium in the central layer 530 is 14% or less. Although not shown in FIG. 7, the film thickness of each layer of the central layer 530 is about 220 nm. The piezoelectric element 5 of Examples 1 to 10 includes the first hydrogen absorption layer 54, the second hydrogen absorption layer 55, and the third hydrogen absorption layer 524.

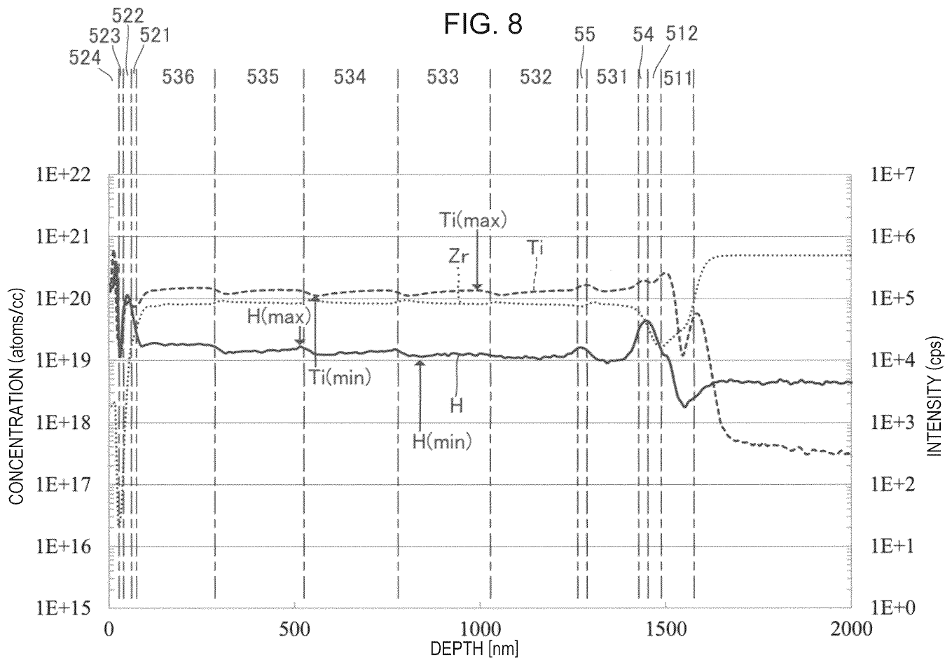

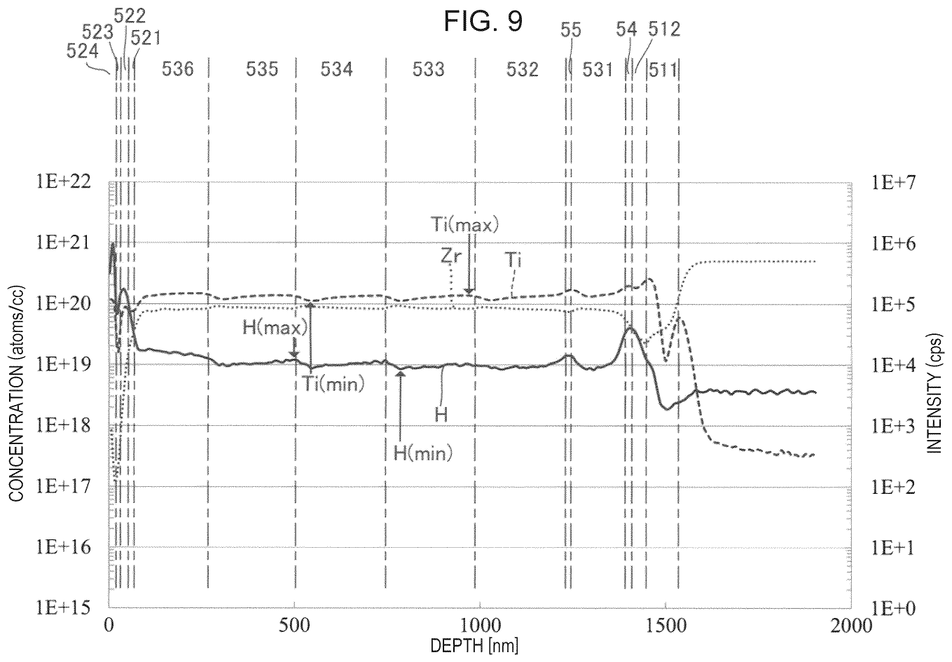

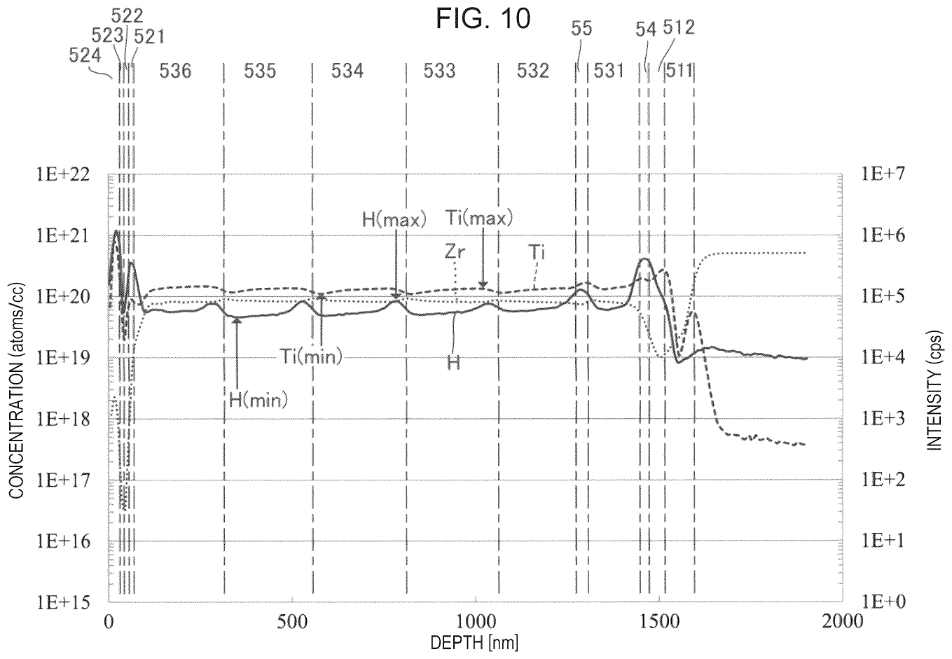

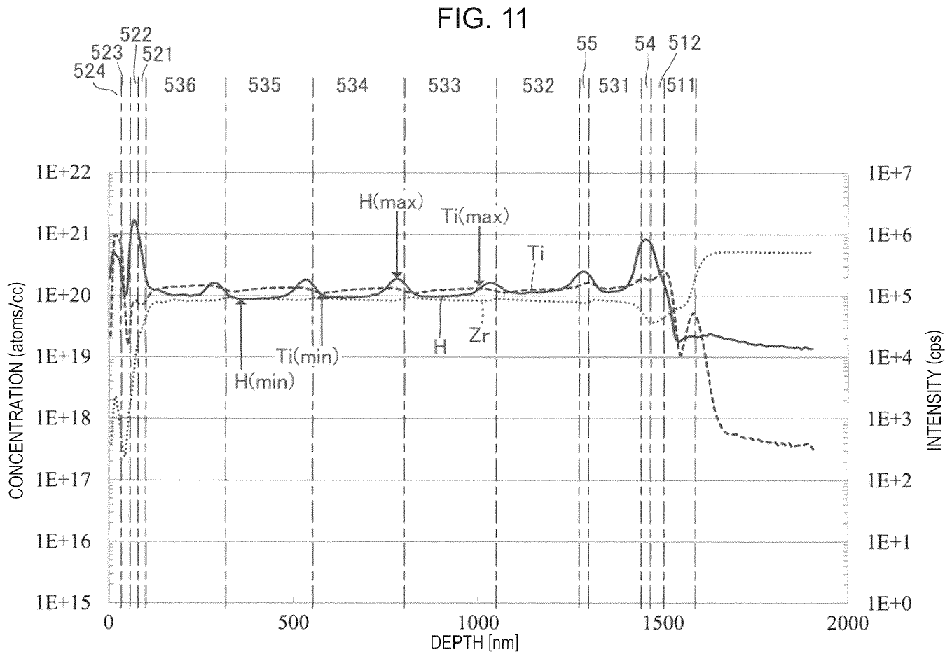

FIG. 8 is a diagram showing a measurement result of the piezoelectric element 5 of Example 1 with a secondary ion mass spectrometer (SIMS). FIG. 9 is a diagram showing a measurement result of the piezoelectric element 5 of Example 2 with a secondary ion mass spectrometer. FIG. 10 is a diagram showing a measurement result of the piezoelectric element 5 of Comparative Example 1 with a secondary ion mass spectrometer. FIG. 11 is a diagram showing a measurement result of the piezoelectric element 5 of Comparative Example 2 with a secondary ion mass spectrometer.

In Examples 1 and 2 and Comparative Examples 1 and 2, the material of the first electrode layer 511 is platinum, and the material of the second electrode layer 512 is iridium. The first hydrogen absorption layer 54 includes titanium. The second hydrogen absorption layer 55 includes titanium. The material of the third electrode layer 521 is iridium oxide, the material of the fourth electrode layer 522 is titanium oxide, the material of the fifth electrode layer 523 is iridium, and the material of the third hydrogen absorption layer 524 is titanium.

The horizontal axis of FIG. 8 to FIG. 11 is depth [nm]. Since the analysis was performed in the Z1 direction from the upper electrode 52, the shallower side is the upper electrode 52 side, and the deeper side is the lower electrode 51 side. The vertical axis of FIG. 8 to FIG. 11 indicates the concentration of hydrogen [atoms/cc]. The concentration of hydrogen is a result of quantification using a standard sample doped with a target element at a known concentration. Titanium and zirconium are indicated in terms of ion intensity. “E” represents a power of 10. For example, 1E+20 represents 1×10²⁰, and 1E+19 represents 1×10¹⁹.

In FIGS. 8 to 11, a clear line segment is drawn along the interface of each layer, but the position of the interface is slightly shifted depending on determined contents. Due to a measurement error of SIMS, the interface effect, or the like, peak positions may be shifted with respect to the depths at which the first hydrogen absorption layer 54 and the second hydrogen absorption layer 55 are positioned. In this case, the peaks of hydrogen observed in the vicinity of the depths at which the first hydrogen absorption layer 54 and the second hydrogen absorption layer 55 are positioned are regarded as peak values in the first hydrogen absorption layer 54 and the second hydrogen absorption layer 55.

FIG. 8 to FIG. 11 show H(max), H(min), Ti(max), and Ti(min). Each of Example 1 of FIG. 8 and Example 2 of FIG. 9 has a smaller change rate ΔH of the content of hydrogen in the central layer 530 than Comparative Example 1 of FIG. 10 and Comparative Example 2 of FIG. 11. Each of Example 1 of FIG. 8 and Example 2 of FIG. 9 has a smaller change rate ΔTi of the content of titanium in the central layer 530 than Comparative Example 1 of FIG. 10 and Comparative Example 2 of FIG. 11. In FIG. 8 to FIG. 11, Ti is indicated in terms of secondary ion intensity.

H(ave) and Ti(ave) of the central layer 530 were calculated by averaging the content of hydrogen and the content of titanium from the interface on one end side to the interface on the other end side of the central layer.

In Example 1 of FIG. 8, the average hydrogen content of the third layer 533 is smaller than the average hydrogen content of the fourth layer 534 and the average hydrogen content of the fifth layer 535. The average hydrogen content of the fourth layer 534 is smaller than the average hydrogen content of the fifth layer 535.

### 1-5. Manufacturing Method of Piezoelectric Element 5

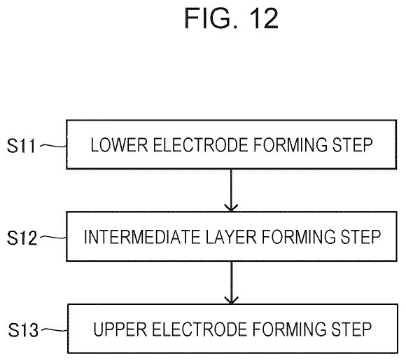

FIG. 12 is a diagram showing a procedure of a manufacturing method of the piezoelectric element 5 of FIG. 6. As shown in FIG. 12, the manufacturing method of the piezoelectric element 5 includes a lower electrode forming step S11, an intermediate layer forming step S12, and an upper electrode forming step S13. These steps are performed in this order.

In the lower electrode forming step S11, the lower electrode 51 is formed. The lower electrode forming step S11 includes formation of the first electrode layer 511 and formation of the second electrode layer 512. Specifically, first, for example, a layer including a conductive material such as platinum is formed on the vibrating plate 33 using sputtering, vapor deposition, or chemical vapor deposition (CVD), thereby forming the first electrode layer 511. Next, for example, a layer including a conductive material such as iridium is formed on the first electrode layer 511 using sputtering, vapor deposition, or CVD, thereby forming the second electrode layer 512.

The intermediate layer forming step S12 includes formation of the first hydrogen absorption layer 54, formation of the piezoelectric layer 53, and formation of the second hydrogen absorption layer 55. Specifically, first, a layer including a hydrogen storage material such as titanium is formed on the lower electrode 51 using sputtering, vapor deposition, or CVD. Next, a film of a first layer precursor formed of a perovskite type composite oxide such as PZT is formed on the layer including a hydrogen storage material using a sol-gel method, and is degreased. Next, the layer including a hydrogen storage material and the first layer precursor are fired. As a result, the first hydrogen absorption layer 54 and the first layer 531 are formed.

Next, another layer including a hydrogen storage material such as titanium is formed on the first layer 531 using sputtering, vapor deposition, or CVD. Next, a film of a second layer precursor formed of a perovskite type composite oxide such as PZT is formed on the other layer including a hydrogen storage material by a sol-gel method, and is degreased. Next, the other layer including a hydrogen storage material and the second layer precursor are fired. As a result, the second hydrogen absorption layer 55 and the second layer 532 are formed.

When the second hydrogen absorption layer 55 is formed, the second hydrogen absorption layer 55 may be formed in a state where moisture remains on the surface of the first layer 531. For this reason, it is preferable to perform a heating step for removing moisture on the surface in the formation of the second hydrogen absorption layer 55. Thus, the amount of the moisture remaining on the surface of the first layer 531 can be reduced. Therefore, the amount of hydrogen absorbed by the second hydrogen absorption layer 55 when the second hydrogen absorption layer 55 is formed can be reduced, and thus the formed second hydrogen absorption layer 55 can sufficiently absorb hydrogen.

Next, a film of a third layer precursor formed of a perovskite type composite oxide such as PZT is formed on the second layer 532 using a sol-gel method, and then the third layer precursor is fired. Thus, the third layer 533 is formed. The fourth layer 534, the fifth layer 535, and the sixth layer 536 are formed by the same method. Next, after the formation of the sixth layer 536, the first hydrogen absorption layer 54, the second hydrogen absorption layer 55, and the piezoelectric layer 53 are collectively fired.

When each layer of the piezoelectric layer 53 is formed by a sol-gel method, the shape and crystallinity of a lower layer affect the shape and crystallinity of an upper layer. In the present embodiment, the hydrogen content of the second layer 532 is smaller than the hydrogen content of the third layer 533. Therefore, it is possible to reduce the influence of the shape and crystallinity of the second layer 532 on the third layer 533 at the stage of forming the third layer 533, which is a middle layer portion of the piezoelectric layer 53, by a sol-gel method.

In the upper electrode forming step S13, the upper electrode 52 is formed. The upper electrode forming step S13 includes formation of the third electrode layer 521, formation of the fourth electrode layer 522, formation of the fifth electrode layer 523, and formation of the third hydrogen absorption layer 524. Specifically, for example, a layer including a conductive material such as iridium is formed on the sixth layer 536 using sputtering, vapor deposition, or CVD, and then fired, thereby forming the third electrode layer 521 including a metal oxide or the like. Next, a layer including a conductive material such as titanium is formed on the third electrode layer 521 using sputtering, vapor deposition, or CVD, and then fired, thereby forming the fourth electrode layer 522 including a metal oxide or the like.

Next, a layer including a conductive material such as iridium is formed on the fourth electrode layer 522 using sputtering, vapor deposition, or CVD, thereby forming the fifth electrode layer 523. Next, a layer including a hydrogen storage material such as titanium is formed on the fifth electrode layer 523 using sputtering, vapor deposition, or CVD, thereby forming the third hydrogen absorption layer 524. Thus, the piezoelectric element 5 is manufactured.

### 2. Modification Examples

The embodiment illustrated above may be modified in various ways. Specific aspects of modification that may be applied to the embodiment described above will be illustrated below. Two or more aspects optionally selected from the following examples can be appropriately merged to the extent that they do not contradict each other.

### 2-1. First Modification Example

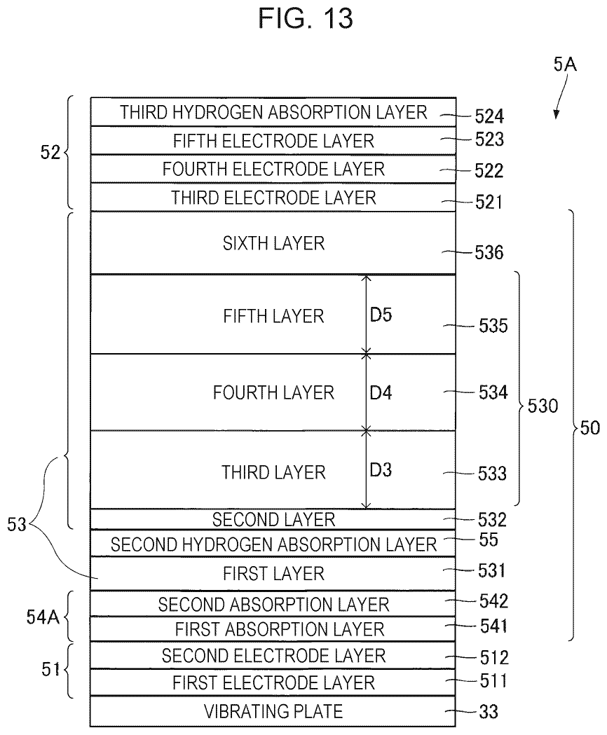

FIG. 13 is a diagram schematically showing a piezoelectric element 5A of a first modification example. As shown in FIG. 13, a first hydrogen absorption layer 54A of the piezoelectric element 5A of the first modification example includes a plurality of layers made of different main constituent materials. Specifically, the first hydrogen absorption layer 54A includes a first absorption layer 541 and a second absorption layer 542. The second absorption layer 542 mainly includes a material different from the main constituent material mainly constituting the first absorption layer 541. The first absorption layer 541 is formed of, for example, titanium. The second absorption layer 542 is formed of, for example, lead zirconate (PbZrO₃) or lead titanate (PbTiO₃). The main constituent material refers to a material contained in an amount of 50% or more of the materials constituting the layer.

When the first hydrogen absorption layer 54A includes a plurality of layers, the entry of hydrogen into the piezoelectric layer 53 can be more effectively inhibited than a single layer.

The first absorption layer 541 and the second absorption layer 542 may be different from or the same as each other in hydrogen absorption performance, that is, the amount of hydrogen absorbed. The second absorption layer 542 may function as the orientation control layer described above.

In the first embodiment and the first modification example, a portion of the lower electrode 51 may be regarded as a portion of the first hydrogen absorption layer 54. Also in this case, the first hydrogen absorption layer 54 is regarded as including a plurality of layers. For example, the second electrode layer 512 of the lower electrode 51 may be regarded as a portion of the first hydrogen absorption layer 54. The first hydrogen absorption layer 54 may have a function as an electrode.

### 2-2. Second Modification Example

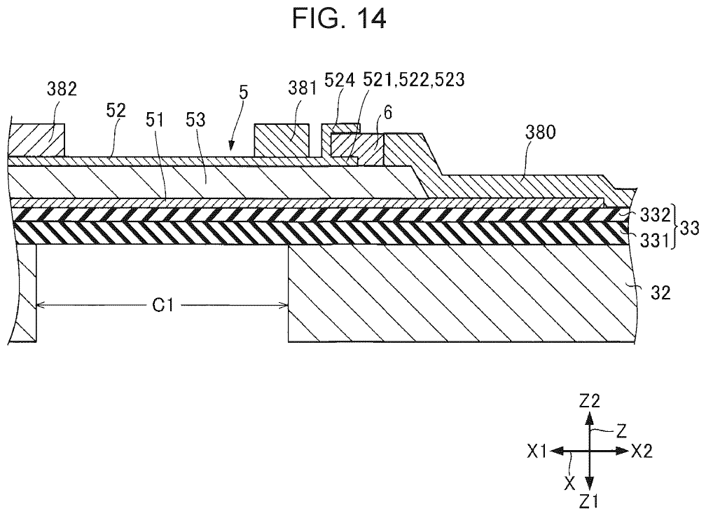

FIG. 14 is a cross-sectional view of the piezoelectric element 5 of a second modification example. As shown in FIG. 14, a protective film 6 is disposed on the upper surface of the piezoelectric layer 53. Specifically, the protective film 6 is disposed on one end of the piezoelectric layer 53 along the X axis. A portion of the upper surface of the piezoelectric layer 53 is not covered with the upper electrode 52 and is exposed. The protective film 6 is disposed on the exposed portion. The protective film 6 includes, for example, ceramics such as aluminum oxide (AlOx) and silicon nitride.

When the protective film 6 is provided on the exposed portion of the piezoelectric layer 53, hydrogen can be inhibited from entering the piezoelectric layer 53. A portion of the protective film 6 is embedded in the upper electrode 52. Specifically, the third electrode layer 521, the fourth electrode layer 522, and the fifth electrode layer 523 are disposed below the protective film 6. The third hydrogen absorption layer 524 is disposed above the protective film 6. When a portion of the third hydrogen absorption layer 524 is provided on the third hydrogen absorption layer 524, hydrogen in the protective film 6 can be absorbed by the third hydrogen absorption layer 524, and hydrogen in the protective film 6 can be inhibited from entering the piezoelectric layer 53.

The third hydrogen absorption layer 524 may be disposed below the protective film 6. The third hydrogen absorption layer 524 is provided on a portion of the upper surface of the protective film 6, but may be provided on the entire upper surface of the protective film 6.

When the protective film 6 is provided, the protective film 6 is formed during the formation of the third hydrogen absorption layer 524 after the third electrode layer 521, the fourth electrode layer 522, and the fifth electrode layer 523 are formed in the manufacturing method of the piezoelectric element 5. The protective film 6 is mainly formed on an exposed portion of the upper surface of the piezoelectric layer 53 where the third electrode layer 521, the fourth electrode layer 522, and the fifth electrode layer 523 are not provided. The protective film 6 is formed by forming a ceramic material into a film using sputtering, vapor deposition, or CVD.

### 2-3. Other Modification Examples

The “liquid ejection head” may be a circulation type head having a so-called circulation flow path.

The “image forming apparatus” can be adopted in various apparatuses, such as a facsimile machine and a copying machine, in addition to an apparatus dedicated to printing. The use of the image forming apparatus is not limited to printing. For example, an image forming apparatus that ejects a solution of a coloring material is used as a manufacturing apparatus that forms a color filter of a display device such as a liquid crystal display panel. An image forming apparatus that ejects a solution of a conductive material is used as a manufacturing apparatus that forms wiring or an electrode of a wiring board. An image forming apparatus that ejects a solution of an organic substance relating to a living body is used as, for example, a manufacturing apparatus that manufactures a biochip.

Although the present disclosure has been described above based on the preferred embodiments, the present disclosure is not limited to the above-described embodiments. The configuration of each section of the present disclosure can be replaced with any configuration having the same function in the above-described embodiments, and any configuration can be added.

What is claimed is:

1. A piezoelectric element comprising:
a piezoelectric layer including a plurality of layers; and
a pair of electrodes disposed with the piezoelectric layer interposed between the electrodes, wherein
the piezoelectric layer is formed of lead zirconate titanate, and
ΔH is 24% or less when an average value, a maximum value, and a minimum value of a content of hydrogen contained in a plurality of central layers of the piezoelectric layer are defined as H(ave), H(max), and H(min), respectively, and a larger one of absolute values of (H(max)−H(ave))/H(ave)) and (H(min)−H(ave))/H(ave)) is defined as ΔH as a change rate of the content of hydrogen.

2. The piezoelectric element according to claim 1, wherein the change rate ΔH is 20% or less.

3. The piezoelectric element according to claim 1, wherein in the central layers of the piezoelectric layer, an average hydrogen content of a lower layer in a stacking direction is smaller than an average hydrogen content of an upper layer.

4. The piezoelectric element according to claim 1, wherein in one layer of the central layers of the piezoelectric layer, a hydrogen content on a lower side is larger than a hydrogen content on an upper side.

5. The piezoelectric element according to claim 1, wherein a film thickness of one central layer of the layers is 100 nm or more and 300 nm or less.

6. The piezoelectric element according to claim 1, wherein ΔTi is 14% or less when an average value, a maximum value, and a minimum value of a content of titanium contained in the layers are defined as Ti(ave), Ti(max), and Ti(min), respectively, and a larger one of absolute values of (Ti(max)−Ti(ave))/Ti(ave)) and (Ti(min)−Ti(ave))/Ti(ave)) is defined as ΔTi as a change rate of the content of titanium.

7. The piezoelectric element according to claim 2, wherein ΔTi is 14% or less when an average value, a maximum value, and a minimum value of a content of titanium contained in the layers are defined as Ti(ave), Ti(max), and Ti(min), respectively, and a larger one of absolute values of (Ti(max)−Ti(ave))/Ti(ave)) and (Ti(min)−Ti(ave))/Ti(ave)) is defined as ΔTi as a change rate of the content of titanium.

8. The piezoelectric element according to claim 1, comprising hydrogen absorption layers at positions interposing the piezoelectric layer between the hydrogen absorption layers in a stacking direction of the layers.

9. A liquid ejection head comprising the piezoelectric element according to claim 1.
